(19) United States
(12) Patent Application Publication
(10) Pub. No.: US 2026/0237967 A1
(43) Pub. Date: Aug. 13, 2026

(54) TUNABLE TRANSVERSE CAVITY SURFACE EMITTING LASER

(71) Applicant: University of Florida Research Foundation, Incorporated, Gainesville, FL (US)

(72) Inventors: Hamed Dalir, Gainesville, FL (US); Elham Heidari, Gainesville, FL (US); Tongyao Wu, Gainesville, FL (US)

(21) Appl. No.: 19/463,961

(22) Filed: Jan. 29, 2026

Related U.S. Application Data
(60) Provisional application No. 63/756,509, filed on Feb. 10, 2025.

(51) Int. Cl. H01S 5/10; H01S 5/183

(52) U.S. Cl. CPC H01S 5/1021; H01S 5/183

(57) ABSTRACT

A transverse cavity surface emitting laser (TCSEL) comprising an active cavity comprising a gain factor; a feedback cavity comprising a loss factor; and a coupling channel that transversely couples the active cavity to the feedback cavity, wherein (i) the TCSEL is configured to operate at or near an exceptional point (EP) based on a gain/loss contrast between the active cavity and the feedback cavity, (ii) the gain/loss contrast corresponds to the gain factor and the loss factor, and (iii) a wavelength of a laser emitted from the TCSEL is tunable by tuning the loss factor.

### CROSS REFERENCE TO RELATED APPLICATION

This application claims the priority of U.S. Provisional Application No. 63/756,509, entitled “TUNABLE TRANSVERSE CAVITY SURFACE EMITTING LASER,” filed on Feb. 10, 2025, the disclosure of which is hereby incorporated by reference in its entirety.

### BACKGROUND

Vertical-cavity surface-emitting lasers (VCSELs) may provide advantages, such as in fabrication cost, energy consumption, temperature stability, and dense-array fabrication complexity. However, limitations in wavelength tunability of traditional VCSELs have generally inhibited the usage of traditional VCSELs in certain applications. Existing methods, such as electro-thermal tuning, micro-electromechanical structure (MEMS) VCSEL, high contrast gratings (HCGs), and liquid crystal integration suffer from certain deficiencies. For instance, electro-thermal tuning may be simple and stable but suffers from slow response time and high-power consumption. MEMS-based tuning may provide a considerable tuning range but is not reliable in terms of mechanical stability. HCG may also provide a considerable tuning range with high efficiency, but fabrication and integration challenges limit its application. Accordingly, Applicant has identified technical challenges and difficulties associated with traditional VCSELs.

### BRIEF SUMMARY

Various embodiments described herein relate to a transverse cavity surface emitting laser (TCSEL). According to some embodiments, a transverse cavity surface emitting laser (TCSEL) comprises an active cavity comprising a gain factor; a feedback cavity comprising a loss factor; and a coupling channel that transversely couples the active cavity to the feedback cavity, wherein (i) the TCSEL is configured to operate at or near an exceptional point (EP) based on a gain/loss contrast between the active cavity and the feedback cavity, (ii) the gain/loss contrast corresponds to the gain factor and the loss factor, and (iii) a wavelength of a laser emitted from the TCSEL is tunable by tuning the loss factor.

In some embodiments, the wavelength of the laser is tunable based on a square-root dependency of the wavelength on an induced loss in the feedback cavity. In some embodiments, the EP is achieved when (i) the gain/loss contrast is equal to a coupling between the active cavity and the feedback cavity and (ii) parity-time (PT) symmetry is preserved. In some embodiments, the loss factor is tunable by applying a negative bias voltage to the feedback cavity. In some embodiments, the gain factor is controlled by an injection current. In some embodiments, the active cavity comprises a vertical-cavity surface-emitting laser (VCSEL) cavity. In some embodiments, the feedback cavity comprises a slow-light cavity. In some embodiments, the slow-light cavity is configured such that light propagates transversely in a zig-zag manner between the active cavity and the slow-light cavity. In some embodiments, the active cavity, the feedback cavity, and the coupling channel form a bowtie-shaped transversely coupled cavity structure.

According to some embodiments, a TCSEL comprises an active VCSEL cavity comprising a gain medium; a slow-light cavity transversely coupled to the active VCSEL cavity; and a coupling channel connecting the active VCSEL cavity and the slow-light cavity, wherein (i) the TCSEL is configured to operate at or near an exceptional point (EP) based on a gain/loss contrast between the active VCSEL cavity and the slow-light cavity, (ii) a wavelength of a laser emitted from the TCSEL is tunable based on a nonlinear effect at the EP, and (iii) the nonlinear effect comprises a square-root dependency of the wavelength on an induced loss in the slow-light cavity.

In some embodiments, the active VCSEL cavity and the slow-light cavity form a bowtie-shaped transversely coupled cavity structure. In some embodiments, the slow-light cavity is configured such that photons from the active VCSEL cavity travel through the coupling channel to the slow-light cavity and reflect back with a reduced group velocity.

### BRIEF DESCRIPTION OF THE DRAWINGS

Embodiments incorporating teachings of the present disclosure are shown and described with respect to the figures presented herein.

FIG. 1 depicts a cross-sectional view of an example vertical-cavity surface-emitting laser (VCSEL).

FIG. 2 depicts a pair of transversely coupled VCSEL cavities in accordance with some embodiments of the present disclosure.

FIGS. 3A, 3B, 3C, and 3D depict example plots of wavelength and effective gain/loss mapped to detuning and loss tuning in accordance with some embodiments of the present disclosure.

FIG. 4 depicts an example TCSEL structure in accordance with some embodiments of the present disclosure.

FIG. 5A depicts an example plot of wavelength tunability with respect to effective gain/loss in accordance with some embodiments of the present disclosure.

FIG. 5B depicts an example plot of wavelength tunability with respect to coupled mode theory in accordance with some embodiments of the present disclosure.

FIG. 6 depicts an example fabrication of a TCSEL in accordance with some embodiments of the present disclosure.

### DETAILED DESCRIPTION

Various embodiments of the present disclosure now will be described more fully hereinafter with reference to the accompanying drawings, in which some, but not all embodiments of the disclosure are shown. Indeed, the disclosure may be embodied in many different forms and should not be construed as limited to the embodiments set forth herein. Rather, these embodiments are provided so that this disclosure will satisfy applicable legal requirements. The term “or” is used herein in both the alternative and conjunctive sense, unless otherwise indicated. The terms “illustrative,” “example,” and “exemplary” are used to be examples with no indication of quality level. Like numbers refer to like elements throughout.

### General Overview and Example Technical Improvements

The present disclosure provides a wavelength-tunable transversely coupled cavity (TCC)-vertical-cavity surface-emitting laser (VCSEL) (herein referred to as a transverse cavity surface emitting laser (TCSEL)) by coupling a VCSEL with a feedback cavity. The TCSEL may comprise an active cavity and a feedback cavity that are connected by a narrow coupling channel. As such, when the two cavities are coupled together, a phenomenon known as an exceptional point (EP) may be leveraged to govern the behavior of the TCSEL. In some embodiments, the TCSEL comprises wavelength tunability that is based on a non-linear effect at the EP. In some embodiments, the wavelength tunability is based on optical gain and loss between the active cavity and the feedback cavity. In some embodiments, an on-chip TCSEL operating at approximately 980 nm is configured to provide up to approximately 4.6 nm of wavelength tunability.

In some embodiments, a TCSEL comprises a bowtie-shaped transversely coupled cavity structure that emits a laser at 980 nm. The bowtie transversely coupled cavity structure, where a slow-light effect may significantly influence a coupling rate via prolonging photon travel time, may enable an additional tuning degree of freedom without compromising single-mode lasing operation. An EP may be achieved when a gain/loss contrast between two coupled cavities is tuned properly, in which case a large mode transformation may occur, forming the basis of a tunable laser. In some embodiments, a tunable wavelength range of a TCSEL is configured by varying optical gain and loss between an active cavity and a feedback cavity by controlling an injection current in the active cavity and a negative bias voltage in the feedback cavity. A square root response at the EP may cause a swift and abrupt change of laser wavelength upon a tuning of loss, thereby providing a tunable laser. As such, laser wavelength provided by the TCSEL may configured by varying optical gain and loss between the active cavity and the feedback cavity of the TCSEL in accordance with the EP. Furthermore, laser power may be enhanced with asymmetric cavities.

Accordingly, by implementing TCCs in a VCSEL architecture, an EP may be established to provide a TCSEL structure that is monolithically integrable and wavelength tunable. Thus, various embodiments of the present disclosure provide a significant advancement over traditional VCSEL technology that enables a more compact and efficient wavelength tuning scheme for applications in optical communication and sensing. A TCSEL may outperform conventional tunable lasers in power consumption, fabrication cost, operation speed and stability.

### Example System Architecture

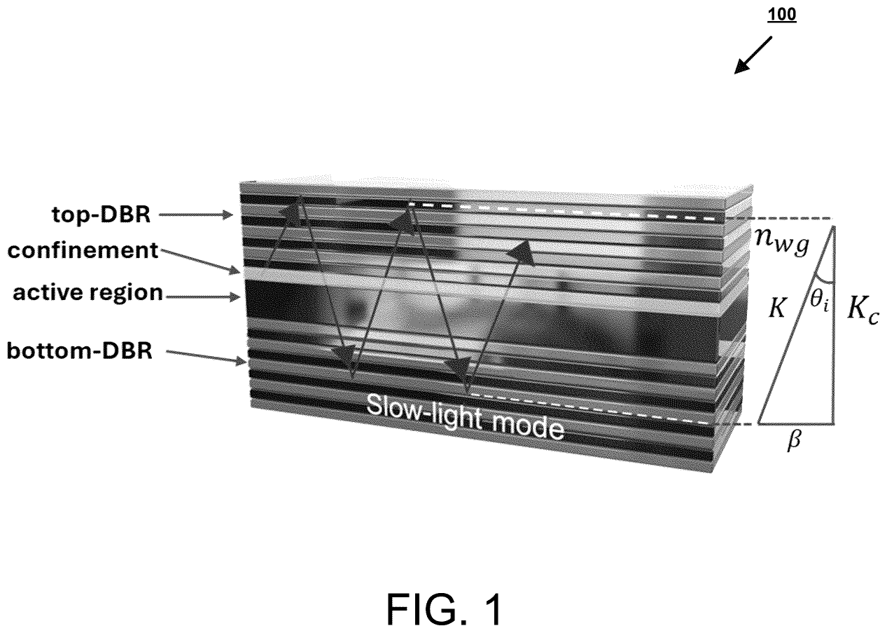

FIG. 1 depicts a cross-sectional view of an example VCSEL 100. The VCSEL 100 may comprise a semiconductor laser that emits light perpendicular to a chip surface. VCSELs, such as VCSEL 100, may be used in a variety of applications, such as optical communications, face recognition, optical mice, and data centers. As such, VCSELs may provide advantages, such as low manufacturing cost, high power efficiency, monolithic integration and easy testing and packaging. Continuous wavelength tunability may be desired in various optical application scenarios, such as in dense wavelength division multiplexed optical communication systems. Thus, a VCSEL comprising a tunable laser with adjustable wavelength may provide sufficient versatility such that the VCSEL may be used in applications across a plurality of scientific, industrial, and/or medical fields.

According to various embodiments of the present disclosure, a TCSEL is provided by configuring a tunable laser source comprising a pair of transversely coupled VCSEL cavities to operate at or near an EP. That is, by combining TCCs of a VCSEL, slow-light optical feedback may be enhanced, thus enabling wavelength tunability. In some embodiments, a TCC comprises a cavity that is connected transversely with another cavity. TCCs may enable the control of light dynamics by providing an efficient energy exchange channel. As such, an implementation of TCCs may facilitate laser tunability and be used to design compact systems with tailored resonance that may be suitable for a range of applications, including laser stabilization, nonlinear optics and optical sensors.

Furthermore, when two cavity modes are coupled together, as in the case of TCCs, a phenomenon known as an EP may occur, which may be leveraged to control the behavior of a system (e.g., TCSEL) formed by the coupling of the cavity modes. An EP may comprise a characteristic point in the parameter space of certain non-Hermitian Hamiltonians. An EP may also comprise degenerate eigenstates and fractional power dispersion, thereby resulting in the EP being substantially sensitivity to external influences. In a system with coupled double cavities (e.g., TCCs), a square root response at the EP may enable a swift and abrupt change of optical modes by changing gain and/or loss, which may be leveraged in a tunable laser. In some embodiments, tunability is provided based on the square-root dependency of the wavelength on the induced loss in the coupled feedback cavity. Additionally, an EP may provide rich physics, such as non-reciprocal mode switching and unidirectional invisibility, which may be useful for advancements in optical communication and signal processing.

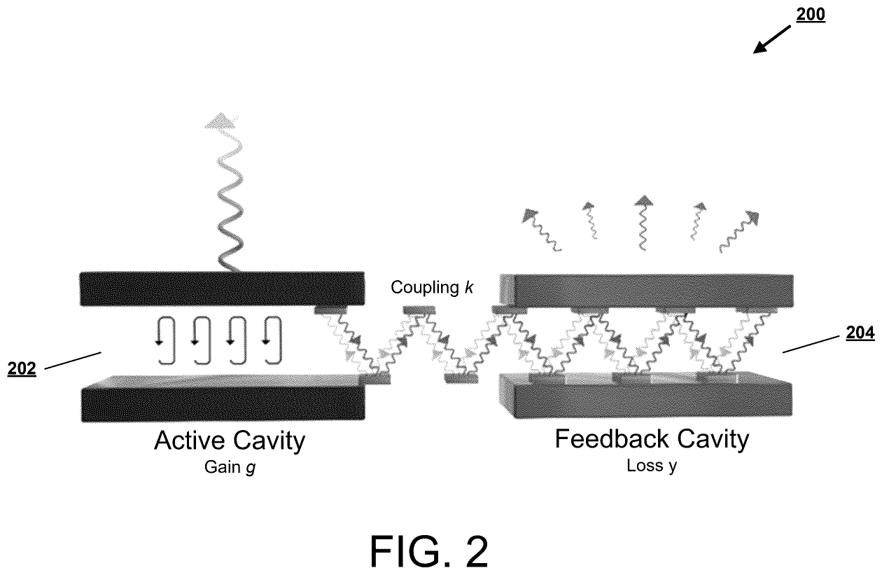

FIG. 2 depicts a pair of transversely coupled VCSEL cavities 200 in accordance with some embodiments of the present disclosure. The pair of transversely coupled VCSEL cavities 200 is representative of a tunable laser that comprises an active cavity 202 that is transversely coupled to a passive feedback cavity 204. Operations at or near an EP may be achieved with the pair of transversely coupled VCSEL cavities 200 by tuning a gain (e.g., gain factor g)/loss (e.g., loss factor γ) contrast between the pair of transversely coupled VCSEL cavities 200. For example, when the gain/loss contrast is tuned to achieve EP, a large mode transformation may occur, thereby providing wavelength tunability and forming the bases of a tunable laser.

The active cavity 202 may comprise a gain factor g and the passive feedback cavity 204 may comprise a loss factor γ. The gain factor g and loss factor γ may quantify how much light intensity increases per unit length in an active medium of the active cavity 202 and in a passive medium of the passive feedback cavity 204.

A coupling effect provided by the pair of transversely coupled VCSEL cavities 200 may be modeled based on the following coupled mode theory:

$$i \frac{d {A}_{1}}{d t} = κ {A}_{2} + ( {ω}_{1} + i g ) {A}_{1} \qquad Equation 1$$

$$i \frac{d {A}_{2}}{d t} = κ {A}_{1} + ( {ω}_{2} - i γ ) {A}_{2} \qquad Equation 2$$

where A₁ and A₂ may represent the amplitudes of the intrinsic cavity modes in the active cavity 202 and the passive feedback cavity 204, respectively, with the frequencies ω₁, ω₂. The coupling between the active cavity 202 and the passive feedback cavity 204 may be denoted by K. Accordingly, the following equation may be derived:

$$i \frac{d}{d t} ( \begin{matrix}{A}_{1} \\ {A}_{2}\end{matrix} ) = ( \begin{matrix}{ω}_{1} + i g & - κ \\ - κ & {ω}_{2} - i γ\end{matrix} ) ( \begin{matrix}{A}_{1} \\ {A}_{2}\end{matrix} ) \qquad Equation 3$$

resembling the Schrödinger equation in quantum mechanics. As such, supermodes in the pair of transversely coupled VCSEL cavities 200 may be represented by a weighted superposition of the original cavity mode frequencies ω₁, ω₂, with supermode frequencies expressed as,

$${ω}_{\pm } = \frac{{ω}_{1} + {ω}_{2}}{2} + i \frac{g - γ}{2} \pm \sqrt{{( \frac{{ω}_{1} - {ω}_{2}}{2} - i \frac{g + γ}{2} )}^{2} + {κ}^{2}} \qquad Equation 4$$

An EP condition may be achieved when the gain/loss between the active cavity 202 and the passive feedback cavity 204 is equal to the coupling κ (e.g., g=γ=κ) and when parity-time (PT)-symmetry is preserved (e.g., ω₁=ω₂=ω₀). A new lasing frequency may comprise a function of γ and κ,

$${ω}_{\pm } = {ω}_{0} \pm \sqrt{{κ}^{2} - {γ}^{2}} \qquad Equation 5$$

Although laser output may originate mostly from the active medium of the active cavity 202, dissipation from the passive medium of the passive feedback cavity 204 may still influence laser wavelength to a large degree, especially near EP. Accordingly, frequency-loss dispersion near EP may be represented by,

$${ω}_{\pm } - {ω}_{E P} = {ω}_{0} \pm \sqrt{κ} \sqrt{{γ}_{E P} - γ} \qquad Equation 6$$

which may yield the quadratic form as the characteristic behavior of EP. The quadratic form may enable a strong nonlinear effect at the EP, which may provide the basis for large wavelength tunability. Near the EP, a square-root response due to the quadratic form may be provided for tuning laser wavelength. Thus, assuming a constant coupling κ, tunability of the pair of transversely coupled VCSEL cavities 200 may be adjusted by the loss γ.

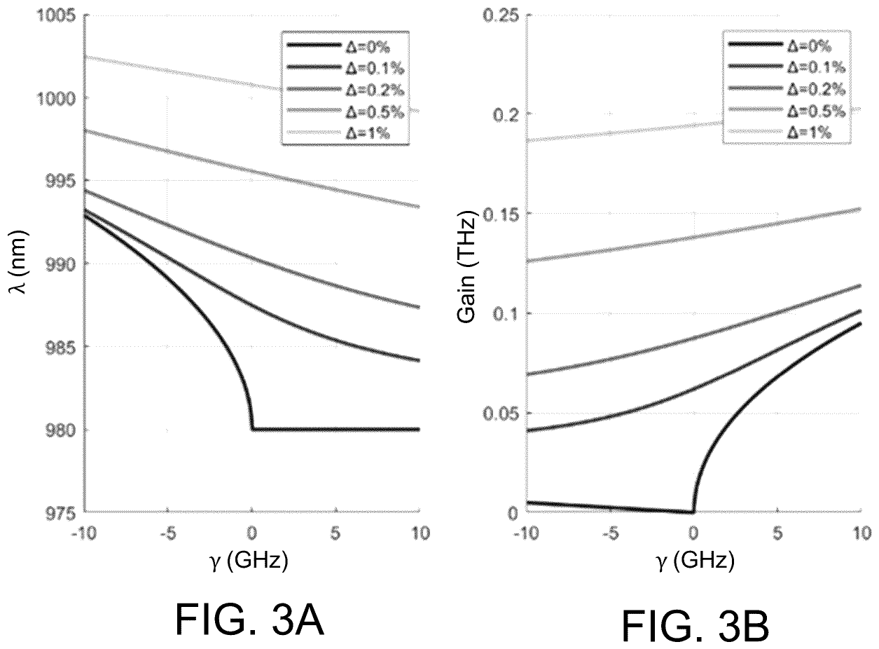

FIGS. 3A, 3B, 3C, and 3D depict example plots of wavelength and effective gain/loss mapped to detuning and loss tuning in accordance with some embodiments of the present disclosure. FIG. 3A depicts a theoretical wavelength tunability of up to 7 nm within 1 THz of loss modification. FIG. 3C depicts that when there is a detuning Δ=ω₁−ω₂≠0 between the active and feedback cavities, the wavelength tunability decreases. However, the gain of an active cavity (e.g., active cavity 202) increases due to an unbalanced field distribution inside of the active cavity and a feedback cavity (e.g., passive feedback cavity 204), as depicted in FIG. 3B. FIG. 3D depicts that for a fixed induced loss of −5 GHz, gain increases with increasing detuning, which may be leveraged to enhance laser power.

For example, TCCs comprising the pair of transversely coupled VCSEL cavities 200 may facilitate slow light, a phenomenon where light propagates at a reduced speed within the structure. A slow-light effect may occur in the TCCs as light propagates transversely in a zig-zag manner between the coupling κ between the cavities in the lateral direction. Slow-light feedback from the TCCs may influence a photon-photon resonance (PPR) effect and increase modulation bandwidth. PPR may be caused by the interaction and interference of optical modes within the TCCs. That is, light from the active cavity may interact with light circulating within the surrounding space of the active cavity as well as of the feedback cavity, leading to a resonance effect that may impact laser dynamics, particularly its modulation bandwidth.

For example, in the TCCs, the light field in the active cavity may permeate through the coupling channel and inject into the feedback cavity with a probability determined by the coupling strength. As light travels slowly between the two cavities, it may undergo multiple round trips (e.g., vertical) between the two cavities and experience gain/loss and/or phase delay. When the light couples back to the active cavity, the photon mode of the light may be significantly modified, leading to a tuned wavelength and different threshold gain.

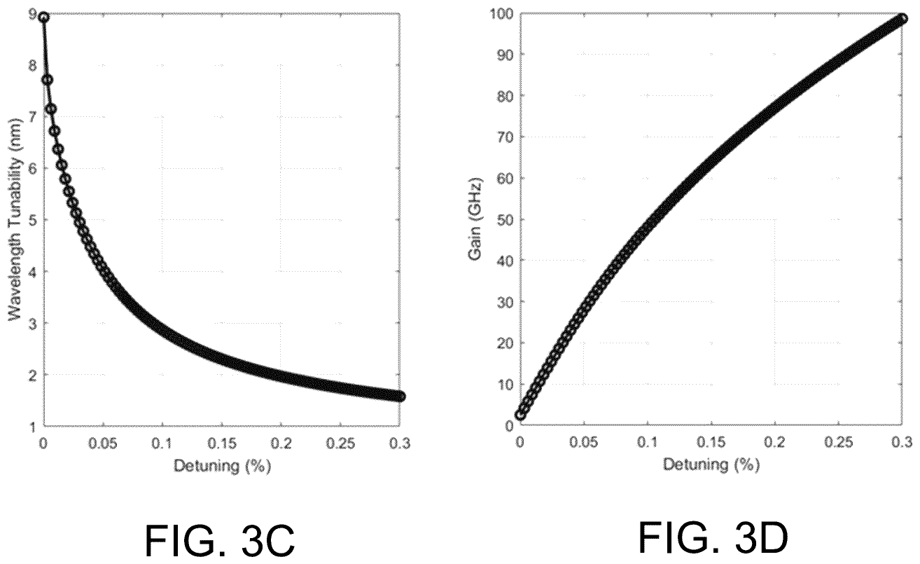

FIG. 4 depicts an example TCSEL structure 400 in accordance with some embodiments of the present disclosure. The TCSEL structure 400 comprises a bowtie-like structure with an active VCSEL cavity 402, comprising a gain medium 404, power gain G, and width W, that is coupled to a slow-light cavity 406. Photons in the active VCSEL cavity 402 and the slow-light cavity 406 are coupled through a coupling channel 408 between them with an equal coupling ratio η. Photons with lifetime τₚ and comprising energy E(t) from the active VCSEL cavity 402 may travel through the coupling channel 408 to the slow-light cavity 406 and reflect back with energy E(t−τ) that is proportional to a reduced group velocity v_{g}=c/n_{g}. The group index n_{g}=fₛn, where c may represent the speed of light, fₛ may represent a slow-light factor, and n may represent the material refractive index. The slow-light cavity 406 comprises a length L_{C}, propagation constant β_{C}, and optical loss α_{C}. A round trip t between the active VCSEL cavity 402 and the far end of the slow-light cavity 406 may be represented by

$$τ = \frac{2 {n}_{g} {L}_{c}}{c} ,$$

where n_{g}=fn may represent a group index with n and f comprising an average material refractive index and a slow-light factor, respectively.

By leveraging PPR between the TCCs, up to approximately 45 GHz modulation bandwidth may be provided. Thus, PPR may be leveraged to achieve significantly enhanced modulation bandwidth, which may enable usage in high-speed optical communication and other applications.

### EXAMPLE EXPERIMENTAL IMPLEMENTATION OF VARIOUS EMBODIMENTS

A laser wavelength may change rapidly around the EP by tuning loss as demonstrated using the TCSEL structure 400, where approximately 4.6 nm wavelength tuning may be achieved. Furthermore, simulation results show the possibility of enhancing laser power with asymmetric cavities. The active VCSEL cavity 402 may comprise a gain factor for wavelengths of approximately 980 nm, while the slow-light cavity 406 may function as a feedback cavity that comprises a loss factor that may be manually tuned by applying voltage.

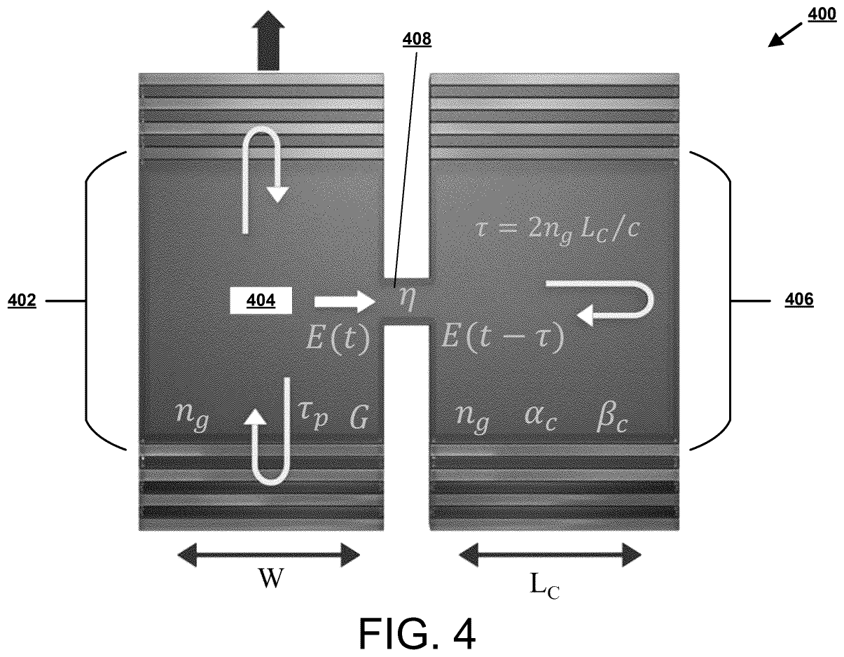

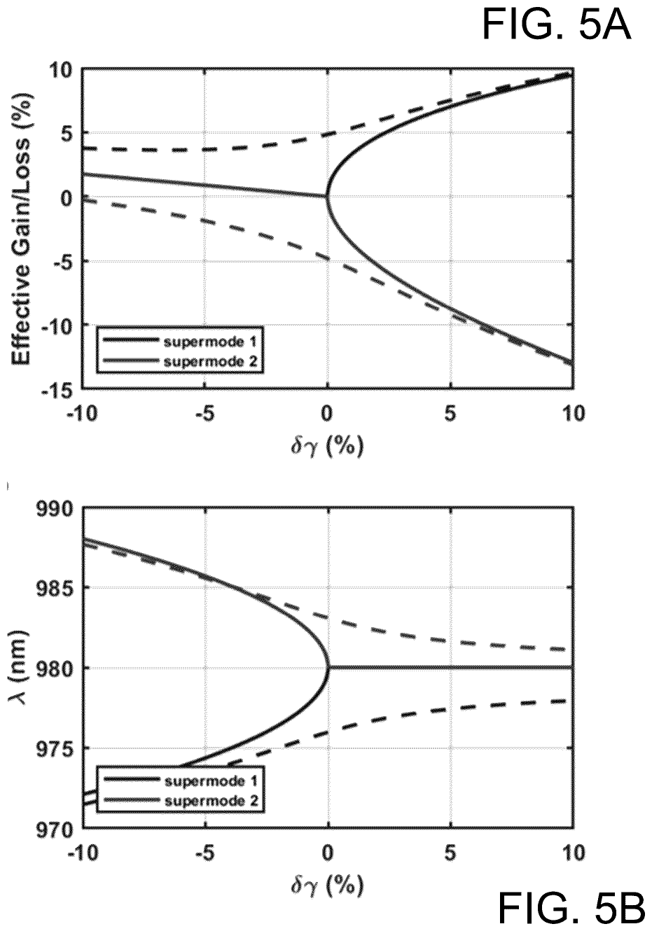

FIG. 5A depicts an example plot of wavelength tunability with respect to effective gain/loss in accordance with some embodiments of the present disclosure. As depicted in FIG. 5A, a tunable 980-nm laser is simulated, where the frequencies of two supermodes are plotted against a loss change in the slow-light cavity, where γ is offset to zero at the EP. Given the condition of PT-symmetric cavities, approximately 10% of loss change may induce approximately an 8 nm wavelength change. Accompanied by redefined frequencies, the two supermodes may be associated with respectively corresponding effective gain/loss factors, which indicate how much gain and loss the two supermodes experience due to photon redistribution in the VCSEL and slow-light cavities.

FIG. 5B depicts an example plot of wavelength tunability with respect to coupled mode theory in accordance with some embodiments of the present disclosure. Accompanied by redefined frequencies, the supermodes may be associated with respectively corresponding effective gain/loss factors, which indicate how much gain and loss the supermodes experience due to photon redistribution in the VCSEL and slow-light cavities. As such, the effective gain/loss factors may comprise deterministic quantities to laser output power and lasing threshold. The two supermodes share the same effective gain/loss factor before EP (γ<γ_{EP}) and becomes inequivalently pumped or dissipated as the parameter goes beyond EP (γ>γ_{EP}). With respect to Equation 4, cavity detuning Δ=ω₁−ω₂ may also be an important factor in modifying the laser output. One consequence of finite detuning is the enhancement of effective gain, with a sacrifice in wavelength tunability. For example, a 0.1% wavelength detuning between the VCSEL and slow-light cavities may lead to additionally 2% of effective (round trip) gain in the vicinity of EP, which may be leveraged to acquire higher laser output, yet wavelength tunability may be reduced by approximately 40%.

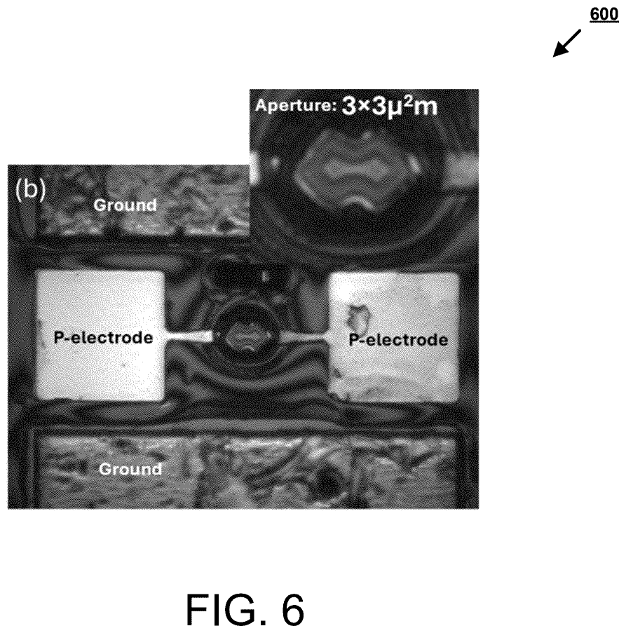

FIG. 6 depicts an example fabrication of a TCSEL 600 in accordance with some embodiments of the present disclosure. The TCSEL 600 comprises a top-emitting 2×1 VCSEL that is fabricated using metal-organic chemical vapor deposition on an n⁺ substrate. The epitaxial structure comprises 35 pairs of silicon-doped bottom distributed Bragg reflectors (DBRs) made of Al_{0.16} Ga_{0.84}As/Al_{0.9} Ga_{0.1}As. The VCSEL active cavity incorporates three 70 Å, In_{0.3} Ga_{0.7}As—GaAs quantum wells, and the top DBR comprises 25 periods. Mesa etched via inductively coupled plasma (ICP) may ensure single transverse mode operation with a low threshold current. Utilizing the Vernier effect, approximately 20 dB side mode suppression ratio (SMSR) is achieved with an effective aperture size of 3×12 μm².

Spatially resolved light is emitted from the feedback cavity or the VCSEL active cavity when biased at 0 V, −0.15 V, −0.25 V, or −0.35 V. With an estimated coupling coefficient of κ=1 THz, a wavelength sweep of 4.6 nm is demonstrated within the PT regime, making it highly suitable for lab-on-a-chip biosensor applications. This performance can be further improved by increasing the coupling coefficient and injecting additional current to compensate for the loss associated with negative bias voltages.

Further expanding the wavelength tuning range and energy efficiency may be provided by increasing the coupling coefficient between the VCSEL and slow-light cavities based on tunability scales as \sqrt{κ}. Having a stronger slow-light effect or a shorter cavity-cavity distance may induce a larger coupling coefficient and thus enhance the tunable wavelength range.

### CONCLUSION

It should be understood that the examples and embodiments described herein are for illustrative purposes only and that various modifications or changes in light thereof will be suggested to persons skilled in the art and are to be included within the spirit and purview of this application.

Many modifications and other embodiments of the present disclosure set forth herein will come to mind to one skilled in the art to which the present disclosures pertain having the benefit of the teachings presented in the foregoing descriptions and the associated drawings. Therefore, it is to be understood that the present disclosure is not to be limited to the specific embodiments disclosed and that modifications and other embodiments are intended to be included within the scope of the appended claim concepts. Although specific terms are employed herein, they are used in a generic and descriptive sense only and not for purposes of limitation.

What is claimed is:

1. A transverse cavity surface emitting laser (TCSEL) comprising:
an active cavity comprising a gain factor;
a feedback cavity comprising a loss factor; and
a coupling channel that transversely couples the active cavity to the feedback cavity,
wherein:
(i) the TCSEL is configured to operate at or near an exceptional point (EP) based on a gain/loss contrast between the active cavity and the feedback cavity,
(ii) the gain/loss contrast corresponds to the gain factor and the loss factor, and
(iii) a wavelength of a laser emitted from the TCSEL is tunable by tuning the loss factor.

2. The TCSEL of claim 1, wherein the wavelength of the laser is tunable based on a square-root dependency of the wavelength on an induced loss in the feedback cavity.

3. The TCSEL of claim 1, wherein the EP is achieved when (i) the gain/loss contrast is equal to a coupling between the active cavity and the feedback cavity and (ii) parity-time (PT) symmetry is preserved.

4. The TCSEL of claim 1, wherein the loss factor is tunable by applying a negative bias voltage to the feedback cavity.

5. The TCSEL of claim 1, wherein the gain factor is controlled by an injection current.

6. The TCSEL of claim 1, wherein the active cavity comprises a vertical-cavity surface-emitting laser (VCSEL) cavity.

7. The TCSEL of claim 1, wherein the feedback cavity comprises a slow-light cavity.

8. The TCSEL of claim 7, wherein the slow-light cavity is configured such that light propagates transversely in a zig-zag manner between the active cavity and the slow-light cavity.

9. The TCSEL of claim 1, wherein the active cavity, the feedback cavity, and the coupling channel form a bowtie-shaped transversely coupled cavity structure.

10. A transverse cavity surface emitting laser (TCSEL) comprising:
an active vertical-cavity surface-emitting laser (VCSEL) cavity comprising a gain medium;
a slow-light cavity transversely coupled to the active VCSEL cavity; and
a coupling channel connecting the active VCSEL cavity and the slow-light cavity,
wherein:
(i) the TCSEL is configured to operate at or near an exceptional point (EP) based on a gain/loss contrast between the active VCSEL cavity and the slow-light cavity,
(ii) a wavelength of a laser emitted from the TCSEL is tunable based on a nonlinear effect at the EP, and
(iii) the nonlinear effect comprises a square-root dependency of the wavelength on an induced loss in the slow-light cavity.

11. The TCSEL of claim 10, wherein the active VCSEL cavity and the slow-light cavity form a bowtie-shaped transversely coupled cavity structure.

12. The TCSEL of claim 10, wherein the slow-light cavity is configured such that photons from the active VCSEL cavity travel through the coupling channel to the slow-light cavity and reflect back with a reduced group velocity.
